(19) United States
(12) Patent Application Publication
(10) Pub. No.: US 2006/0263702 A1
(43) Pub. Date: Nov. 23, 2006

(54) Composition for forming intermediate layer containing sylylphenylene-based polymer and pattern-forming method

(75) Inventors: Naoki Yamashita, Kanagawa (JP); Hisanobu Harada, Kanagawa (JP); Yasushi Fujii, Kanagawa (JP); Yoshinori Sakamoto, Kanagawa (JP)

Correspondence Address: HARNESS, DICKEY & PIERCE, P.L.C., P.O. BOX 828, BLOOMFIELD HILLS, MI, 48303, US

(73) Assignee: Tokyo Ohka Kogyo Co., Ltd., Kawasaki-shi (JP)

(21) Appl. No.: 11/432,689

(22) Filed: May 11, 2006

(30) Foreign Application Priority Data
May 19, 2005 (JP) 2005-146847

(51) Int. Cl. G03F 1/00

(52) U.S. Cl. 430/5

(57) ABSTRACT

A composition for forming an intermediate layer is provided, having improved etching resistance, prevention of reflection of short-wavelength light (ability to absorb short-wavelength light), and low-hardening properties. The composition for forming an intermediate layer includes a silylphenylene-based polymer containing an aromatic ring (A), having a repetitive unit represented by the following general formula (1): 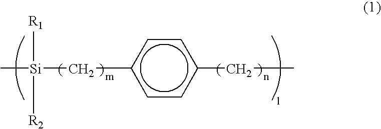
wherein, at least one of R₁ and R₂ is a cross-linking group, m and n are each an integer from 0 to 20, and 1 is an integer representing the number of repetitive units; and a solvent (C).

This application is based on and claims the benefit of priority from Japanese Patent Application No. 2005-146847, filed on 19 May 2005, the content of which is incorporated herein by reference.

### BACKGROUND OF THE INVENTION

1. Field of the Invention

The present invention relates to a composition for forming an intermediate layer, which contains a silylphenylene-based polymer. More specifically, the present invention relates to a photosensitive resin composition for forming an intermediate layer (hard mask) to be formed between a processed layer and a photoresist, the intermediate layer being capable of preventing the reflection of exposure light to be used for patterning the above photoresist layer and having a sufficient difference between the etching rate of the photoresist layer and the etching rate of the processed layer.

2. Related Art

In the production of an integrated circuit device, the miniaturization of processing size in a lithography process for obtaining an integrated circuit having a high integration density has been progressing. In this lithography process, a photosensitive resin composition is applied to the processed layer, exposed to light, and developed to form a resist pattern, followed by patterning a processed film, such as a wiring layer or a dielectric layer, using the resist pattern.

Conventionally, in the above patterning, an exposed region not covered with the resist pattern is removed from the processed film by dry-etching. However, a resist layer (hereinafter, also referred to as a “resist pattern”) is thinned corresponding to a shortened wavelength of an exposure light source or the like for realizing the miniaturization of pattern processing size. In association therewith, the film thickness to be consumed by the completion of etching, that is the thickness of an anti-etching film, may be insufficient. In this way, the conventional resist film cannot ensure a sufficient dry-etching resistance when it is thinned corresponding to the pattern minimaturization. As a result, it is difficult to fabricate the processed film with a high degree of accuracy.

Currently, therefore, for increasing the patterning accuracy of the processed film using a resist pattern as a mask, consideration has been given to inserting an intermediate layer (hard mask) between the processed film and the photoresist layer. For instance, there is proposed a pattern-forming method that enables patterning with good dimensional controllability on a processed film by forming an organic silicon film as an intermediate layer on the processed film, where the organic silicon film has a glass-transition temperature of 0° C. or more and contains an organic silicon compound having a silicon-silicon linkage in its main chain (see, for example, Japanese Patent Application, Laid Open No 10-209134 A).

An intermediate layer to be used for attaining the above object requires various characteristic features such as an etching resistance to etching gas (halogenated gas), prevention of reflection of exposure light (in other words, exposure-light absorption), and low-temperature firing. However, the conventional compositions for forming intermediate layers do not satisfy the various characteristic features mentioned above sufficiently. In the present circumstances, therefore, a composition for forming an intermediate layer satisfying the above characteristic features, particularly both the etching. resistance and exposure-light absorption simultaneously, has been desired.

The present invention has been made in consideration of the aforementioned problem and has as an object the provision of a composition for forming an intermediate layer having improved abilities of etching resistance and prevention of reflection of short-wavelength light (ability to absorb short-wavelength light).

### SUMMARY OF THE INVENTION

For solving the above problem, the present inventors conducted various experiments and studies for obtaining a resin composition suitable for the formation of an intermediate layer having an excellent dry-etching resistance and an ability to absorb short-wavelength light, and they finally found a resin composition containing a silylphenylene-based polymer having an aromatic ring and a solvent (C).

More specifically, the silylphenylene-based polymer containing the aromatic ring is a silylphenylene-based polymer (A) containing an aromatic ring, which has a repetitive unit represented by the following general formula (1): 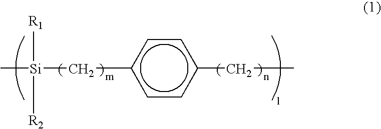
wherein at least one of R₁ and R₂ is a cross-linking group, m and n is each an integer from 0 to 20, and 1 is an integer representing the number of repetitive units.

In other words, the composition for forming an intermediate layer related to the present invention is distinguished by containing:

a silylphenylene-based polymer (A) containing an aromatic ring, which has a repetitive unit represented by the following general formula (1): 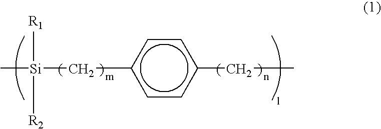
wherein at least one of R₁ and R₂ is a cross-linking group, m and n is each an integer from 0 to 20, and 1 is an integer representing the number of repetitive units; and

a solvent (C).

According to the present invention having the above distinctive configuration, a resin composition (a composition for forming an intermediate layer), which allows the formation of an intermediate layer capable of preventing the reflection of short-wavelength and having a sufficient difference between the etching rate of the photoresist layer and the etching rate of the processed layer, can be provided.

The resin composition preferably contains a cross-linkable catalyst-generating agent (B) that generates a catalytic substance for cross-linking the polymer. The cross-linkable catalyst is an acid or a base. The cross-linkable catalyst-generating agent is an acid-generating agent that generates an acid for cross-linking the polymer by receiving heat or light or a base-generating agent that generates a base for cross-linking the polymer by receiving heat or light.

Furthermore, the pattern-forming method of the present invention is distinguished by including the steps of:

forming an intermediate layer by applying to the processed layer a composition using a cross-linkable catalyst-generating agent that generates an acid or a base by receiving light among the compositions for forming the intermediate layer and then pre-baking the applied film to form an intermediate layer; forming a resist pattern such that a resist pattern is formed on the intermediate layer formed in the step of forming the intermediate layer; and etching to form a pattern on the intermediate layer such that at least the intermediate layer is subjected to dry-etching using the resist pattern formed in the step of forming the resist pattern as a mask.

The intermediate layer prepared from the composition for forming an intermediate layer of the present invention has a high absorbability of short-wavelength light and also has an etching rate sufficiently different from that of the photoresist layer (the upper layer) and that of the processed layer (the lower layer), respectively. Here, a difference in etching rate means a sufficient etching rate with respect to the photoresist film and a substantially low etching rate with respect to the processed film.

The high absorbability of short-wavelength light is a characteristic feature obtained due to the fact that the silylphenylene-based polymer (A) contains an aromatic ring in its structure. In addition, the present composition has a high dry-etching resistance to exposure light due to the fact that the above major polymer (A) is a silylphenylene-based polymer. The silylphenylene-based polymer has a high resistance to halogenated gas used as dry-etching gas. Furthermore, the major polymer (A) includes at least one substitute portion which is cross-linkable by an acidic or basic action with respect to one Si atom, so that a film having an excellent solvent-resistant ability can be obtained even after low-temperature sintering (for example, at 250° C.).

Consequently, the formation of an intermediate layer using the composition for forming an intermediate layer in the present invention can realize the patterning of a processed layer using a resist pattern with high dimensional accuracy.

### BRIEF DESCRIPTION OF THE DRAWINGS

FIG. 1 is a graph representing simulated values for reflectance of short-wavelength light of an intermediate layer prepared from a composition for forming the intermediate layer in the present invention.

### DETAILED DESCRIPTION OF THE INVENTION

Embodiments of the present invention will be described below.

The characteristic feature of the composition for forming an intermediate layer (hard mask) in the present invention is the inclusion of a silylphenylene-based polymer (A) having a repetitive unit represented by the following general formula (1): 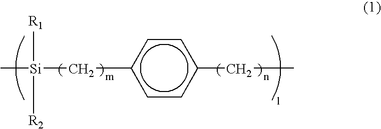
wherein at least one of R₁ and R₂ is a cross-linking group, m and n is each an integer from 0 to 20, and 1 is an integer representing the number of repetitive units; and a solvent (C).

Preferably, the composition for forming an intermediate layer (hard mask) contains a cross-linkable catalyst-generating agent (B) that generates a catalytic substance for cross-linking the polymer.

[1] Silylphenylene-Based Polymer (A)

Silylphenylene-based polymer (A) used in the present invention is a polymer having a repetitive unit represented by the general formula (1).

The above R₁ and R₂ are monovalent organic groups and at least one of them is a cross-linking group (cross-linkable group). Examples of the cross-linking groups include an alkyl group having 1 to 40 carbon atoms (however, it may have an ether bond) with an epoxy group a glycidyl group or an oxetanyl group. For the cross-linking group, particularly preferable is the alkyl group having 1 to 40 carbon atoms (however, it may have an ether bond) with an oxetanyl group. Furthermore, the cross-linking group is preferably one in which R₂ is —(CH₂)ₓO(CH₂)_{y}C(CH₂OCH₂)(CH₂)_{z}CH₃ (wherein x is an integer from 1 to 20, y is an integer from 1 to 20, and z is an integer from 0 to 20).

In addition, the monovalent organic group may be a hydrogen atom or an alkyl or aryl group having 1 to 40 carbon atoms. Examples of such an alkyl group include a methyl group, an ethyl group, a propyl group, an isopropyl group, an n-butyl group, a sec-butyl group, a tert-butyl group, a cycropenthyl group, a cycrohexyl group, a 2-ethylhexyl group, an n-octyl group, and a hexadecanyl group. Among them, the methyl group is preferable because it can be easily synthesized and the raw material thereof is be readily available.

The silylphenylene-based polymer (A) can be prepared, for example, as follows:

A compound represented by the following formula (2) is subjected to a hydrosilylation reaction with a compound having a carbon-carbon double bond on its molecular end and a cross-linking group as a residual group on the double bond, resulting in a silylphenylene-based polymer (A) 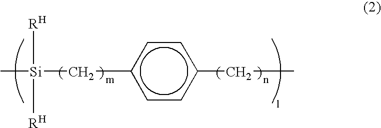
(wherein R^{H} is a hydrogen atom or an alkyl or aryl group having 1 to 40 carbon atoms and at least one of two R^{H} is a hydrogen atom).

Furthermore, the compound (2) can be easily obtained by a Grignard reaction between compounds of the following formulae (3) and (4):

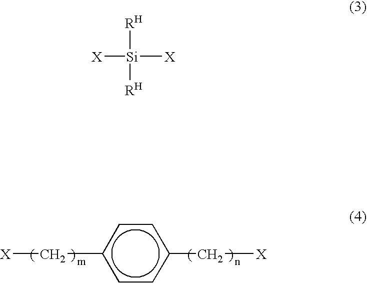

An intermediate layer (hard mask) prepared from the above composition for forming the intermediate layer has a film thickness, not uniformly limited according to application, with a lower limit of 10 nm or more, and more preferably 30 nm or more limit, and an upper limit of 1,000 nm or less, preferably 500 nm or less, more preferably 300 nm or less.

Furthermore, as described above, the polymer concentration in the composition for forming an intermediate layer is adjustable when the solubility of the polymer (A) to the solvent (C) is controlled. Thus, such a polymer concentration helps in adjusting the film thickness of an intermediate layer (hard mask) that is formed.

The intermediate layer (hard mask) prepared from the above composition for forming the intermediate layer contains a compound represented by the above general formula (1) having an aromatic ring in its repetitive structure, so that it can have excellent antireflection properties. In particular, it has excellent antireflection properties for rays of light having a short-wavelength of about 193 nm. Furthermore, the backbone of the above general formula (1) is a silylphenylene-based material, so that it has excellent etching resistance to etching gas, particularly halogenated gases such as CF₄, C₄F₈, CHF₃, CH₂F₂, or SF₆, compared with an inorganic converting film such as a polysilicon film, an oxide silicon film, or a silicon nitride film. Furthermore, since a resist layer formed on the intermediate layer (hard mask) is an organic layer, it has better etching resistance to the etching gas, than the above mentioned intermediate layer.

A preferable silylphenylene-based polymer (A) to be used in the composition for forming an intermediate layer in the present invention is one having the general formula (1) wherein the number of repetitive units represented by 1 is in the range of 1 to 200 and the weight average molecular weight is in the range of 100 to 10,000, preferably 1,000 to 5,000. This is mainly because the flatness of the film can be easily secured, and etching resistance is excellent. Specifically, when the molecular weight of silylphenylene-based polymer (A) is too low, it volatilizes and thus the film formation may fail. Furthermore, the weight average molecular weight of the polymer (A) can be determined by the method of gel permeation chromatography.

[2] Cross-Linkable Catalyst-Generating Agent (B)

The cross-linkable catalyst-generating agent (B) to be used may be an acid-generating agent that generates an acid upon receiving heat or light or a base-generating agent that generates a base upon receiving heat or light.

The thermal acid-generating agent that generates an acid by receiving heat may be any of conventional thermal acid-generating agent including 2,4,4,6-tetra bromocyclohexadinoene, benzoin tosylate, 2-nitrobenzyl tosylate, another alkylester of an organic sulfonic acid, and a composition containing at least one of these thermal acid-generating agents.

The photosensitive acid-generating agent that generates an acid by receiving light may be any known acid-generating agent including onium salts, diazomethane derivatives, glyoxime derivatives, bis-sulfone derivatives, β-ketosulfone derivatives, di-sulfone derivatives, nitrobenzyl sulfonate derivatives, sulfonate ester derivatives, and sulfonate ester derivatives of an N-hydroxyimide compound.

The onium salts specifically include trifluoromethanesulfonate tetramethylammonium, nonafluorobutanesulfonate tetramethylammonium, nonafluorobutanesulfonate tetra-n-butylammonium, nonafluorobutanesulfonate tetraphenylammonium, p-toluene sulfonate tetramethylammonium, trifluoromethanesulfonate diphenyliodonium, p-toluene sulfonate diphenyliodonium, trifluoromethane sulfonate (p-tert-butoxyphenyl) phenyliodonium, p-toluene sulfonate (p-tert-butoxyphenyl) phenyliodonium, trifluoromethane sulfonate triphenylsulfonium, trifluoromethane sulfonate (p-tert-butoxyphenyl)diphenylsulfonium, trifluoromethane sulfonate bis-(p-tert-butoxyphenyl)phenylsulfonium, trifluoromethane sulfonate tris-(p-tert-butoxyphenyl)sulfonium, p-toluene sulfonate triphenylsulfonium, p-toluene sulfonate (p-tert-butoxyphenyl) diphenylsulfonium, p-toluene sulfonate bis-(p-tert-butoxyphenyl) diphenylsulfonium, p-toluene sulfonate tris-(p-tert-butoxyphenyl) sulfonium, nonafluorobutane sulfonate triphenylsulfonium, butane sulfonate triphenylsulfonium, trifluoromethane sulfonate trimethylsulfonium, p-toluenesulfonate trimethylsulfonium, trifluoromethane sulfonate cyclohexylmethyl (2-oxocyclohexyl) sulfonium, p-toluenesulfonate cyclohexylmethyl (2-oxocyclohexyl) sulfonium, trifluoromethane sulfonate dimethylphenyl sulfonium, p-toluenesulfonate dimethylphenyl sulfonium, trifluoromethane sulfonate dicyclohexyl phenylsulfonium, p-toluene sulfonate dicyclohexyl phenylsulfonium, trifluoromethane sulfonate trinaphthylsulfonium, trifluoromethane sulfonate cyclohexylmethyl (2-oxocyclohexyl) sulfonium, trifluoromethane sulfonate (2-norbonyl)methyl (2-oxocyclohexyl) sulfonium, ethylene-bis-[methyl-(2-oxocyclopentyl) sulfonium trifluoromethane sulfonate], and 1,2′-naphthylcarbonyl methyltetrahydrothiophenium triflate.

The diazomethane derivatives include bis-(benzene sulfonyl) diazomethane, bis-(p-toluene sulfonyl) diazomethane, bis-(xylene sulfonyl) diazomethane, bis-(cyclohexyl sulfonyl) diazomethane, bis-(cyclopenthyl sulfonyl) diazomethane, bis-(n-butylsulfonyl) diazomethane, bis-(isobutylsulfonyl) diazomethane, bis-(sec-butylsulfonyl) diazomethane, bis-(n-propylsulfonyl) diazomethane, bis-(isopropylsulfonyl) diazomethane, bis-(tert-butylsulfonyl) diazomethane, bis-(n-amylsulfonyl) diazomethane, bis-(isoamylsulfonyl) diazomethane, bis-(sec-amylsulfonyl) diazomethane, bis-(tert-amylsulfonyl) diazomethane, 1-cyclohexyl sulfonyl-1-(tert-butylsulfonyl) diazomethane, 1-cyclohexyl sulfonyl-1-(tert-amylsulfonyl) diazomethane, and 1-tert-amylsulfonyl-1-(tert-butylsulfonyl) diazomethane.

The glyoxime derivatives include bis-o-(p-toluene sulfonyl)-α-dimethylglyoxime, bis-o-(p-toluene sulfonyl)-α-diphenyl glyoxime, bis-o-(p-toluene sulfonyl)-α-dicyclohexyl glyoxime, bis-o-(p-toluene sulfonyl)-2,3-pentadione glyoxime, bis-o-(p-toluene sulfonyl)-2-methyl-3,4-pentadione glyoxime, bis-o-(n-butane sulfonyl)-α-dimethyl glyoxime, bis-o-(n-butane sulfonyl)-α-diphenyl glyoxime, bis-o-(n-butane sulfonyl)-α-dicyclohexyl glyoxim, bis-o-(n-butane sulfonyl) 2,3-pentanedione glyoxime, bis-o-(n-butane sulfonyl)-2-methyl-3,4-pentanedione glyoxime, bis-o-(methane sulfonyl)-α-dimethyl glyoxime, bis-o-(trifluoromethane sulfonyl)-α-dimethyl glyoxime, bis-o-(1,1,1-trifluoroethane sulfonyl)-α-dimethyl glyoxime, bis-o-(tert-butane sulfonyl)-α-dimethyl glyoxime, bis-o-(perfluorooctane sulfonyl)-α-dimethyl glyoxime, bis-o-(cyclohexane sulfonyl)-α-dimethyl glyoxime, bis-o-(benzene sulfonyl)-α-dimethyl glyoxime, bis-o-(p-fluorobenzene sulfonyl)-α-dimethyl glyoxime, bis-o-(p-tert-butylbenzene sulfonyl)-α-dimethyl glyoxime, bis-o-(xylene sulfonyl)-α-dimethyl glyoxime, and bis-o-(camphorsulfonyl)-dimethyl glyoxime.

The bis-sulfone derivatives include bis-naphthyl sulfonyl methane, bis-trifluoromethyl sulfonyhl methane, bis-methyl sulfonyl methane, bis-ethyl sulfonyl methane, bis-propyl sulfonyl methane, bis-isopropyl sulfonyl methane, bis-p-toluene sulfonyl methane, and bis-benzene sulfonyl methane.

The β-ketosulfone derivatives include 2-cyclohexylcarbonyl-2-(p-toluene sulfonyl)propane, and 2-isopropylcarbonyl-2-(p-toluene sulfonyl)propane.

The disulfone derivatives include diphenyldisulfone derivatives and dicyclohexyl disulfone derivatives.

The nitrobenzyl sulfonate derivatives include p-toluene sulfonic acid 2,6-dinitrobenzyl and p-toluene sulfonic acid 2,4-dinitorobenzyl.

The sulfonate ester derivatives include 1,2,3-tris-(methane sulfonyloxy)benzene, 1,2,3-tris-(trifluoromethane sulfonyloxy)benzene, and 1,2,3-tris-(p-toluene sulfonyloxy)benzene.

The sulfonate ester derivatives of the N-hydroxyimide compound include N-hydroxysuccinimide methane sulfonate ester, N-hydroxysuccinimide trifluoromethane sulfonate ester, N-hydroxysuccinimide ethane sulfonate ester, N-hydroxysuccinimide-1-propane sulfonate ester, N-hydroxysuccinimide-2-propane sulfonate ester, N-hydroxysuccinimide-1-pentane sulfonate ester, N-hydroxysuccinimide-1-octane sulfonate ester, N-hydroxysuccinimide p-toluene sulfonate ester, N-hydroxysuccinimide-p-methoxybenzene sulfonate ester, N-hydroxysuccinimide-2-chloroethane sulfonate ester, N-hydroxysuccinimide benzene sulfonate ester, N-hydroxysuccinimide-2,4,6-trimethylbenzene sulfonate ester, N-hydroxysuccinimide-1-naphthalene sulfonate ester, N-hydroxysuccinimide-2-naphthalene sulfonate ester, N-hydroxy-2-phenylsuccinimide methane sulfonate ester, N-hydroxymaleimide methane sulfonate ester, N-hydroxymaleimide ethane sulfonate ester, N-hydroxy-2-phenylmaleimide methane sulfonate ester, N-hydroxyglutarimide methane sulfonate ester, N-hydroxyglutarimide benzene sulfonate ester, N-hydroxy phthalimide methane sulfonate ester, N-hydroxyphthalimide benzene sulfonate ester, N-hydroxyphthalimide trifluoromethane sulfonate ester, N-hydroxyphthalimide-p-toluene sulfonate ester, N-hydroxynaphthalimide methane sulfonate ester, N-hydroxynaphthalimide benzene sulfonate ester, N-hydroxy-5-norbornene-2,3-dicarboxyimide methane sulfonate ester, N-hydroxy-5-norbonene-2,3-dicarboxyimide trifluoromethane sulfonate ester, and N-hydroxy-5-norbonene-2,3-dicarboxyimide-p-toluene sulfonate ester.

Furthermore, examples of the thermal base-generating agent that generates a base by receiving heat include: carbamate derivatives such as 1-methyl-1-(4-biphenylyl)ethylcarbamate and 1,1-dimethyl-2-cyanoethylcarbamate; urea and urea derivatives such as N,N-dimethyl-N′-methyl urea; dihydropyridine derivatives such as 1,4-dihydronicotinamide; quaternary ammonium salts of organic silane and organic borane; and dicyandiamide. Furthermore, other examples include guanidine trichloroacetate, methylguanidine trichloroacetate, potassium trichloroacetate, guanidine phenylsulfonyl acetate, guanidine p-chlorophenylsulfonyl acetate, guanidine p-methanesulphonylphenylsulphonyl acetate, potassium phenylpropiolate, guanidine phenylpropiolate, cesium phenylpropiolate, guanidine p-chlorophenylpropiolate, guanidine p-phenylene bis-phenylpropiolate, tetramethylammonium phenylsulfonyl acetate, and tetramethylammonium phenylpropiolate.

Furthermore, examples of the photosensitive base-generating agent that generates a base by receiving light include: optically active carbamates such as triphenylmethanol, benzyl carbamate, and benzoyl carbamate; amides such as o-carbamoyl hydroxylamide, o-carbamoyl oxime, aromatic sulfonamide, alpha lactam, and N-(2-allylethynyl) amide as well as other amides; oxime esters; α-aminoacetophenones; and cobalt complexes. Among them, for example, 2-nitrobenzylcyclohexyl carbamate, triphenylmethanol, o-carbamoyl hydroxylamide, o-carbamoyl oxime, [[(2,6-dinitrobenzyl)oxy]carbonyl]cyclohexylamine, bis-[[(2-nitrobenzyl)oxy]carbonyl]hexane-1,6-diamine, 4-(methylthiobenzoyl)-1-1-morpholinoethane, (4-morpholinobenzoyl)-1-benzyl-1-dimethylaminopropane, N-(2-nitrobenzyloxycarbonyl) pyrrolidine, hexamine cobalt (III) tris-(triphenylmethyl borate), and 2-benzyl-2-dimethylamino-1-(4-morpholinophenyl)-butanone are preferable.

[3] Solvents (C)

The solvents (C) to be used in the present invention include: monovalent alcohols such as methyl alcohol, ethyl alcohol, propyl alcohol, and butyl alcohol; polyvalent alcohols such as ethylene glycol, diethylene glycol, propylene glycol, glycerin, trimethylolpropane, and hexane triol; monoesters of polyalcohols, such as ethyleneglycol monomethylether, ethyleneglycol monoethylether, ethyleneglycol monopropylether, ethyleneglycol monobutylether, diethyleneglycol monomethylether, diethyleneglycol monoethylether, diethyleneglycol monopropylether, diethyleneglycol monobutylether, propyleneglycol monomethylether, propyleneglycol monobutylether, propyleneglycol monopropylether, and propyleneglycol monobutylether; esters such as methyl acetate, ethyl acetate, and butyl acetate; ketones such as acetone, methylethyl ketone, cycloalkyl ketone, and methylisoamyl ketone; and polyvalent alcohol ethers where all hydroxyl groups are alkyl-etherified in polyvalent alcohols such as ethyleneglycol dimethylether, ethyleneglycol diethylether, ethyleneglycol dipropylether, ethyleneglycol dibutylether, propyleneglycol dimethylether (PGDM), propyleneglycol dimethylether, propyleneglycol dibutylether, diethyleneglycol dimethylether, diethyleneglycol methylethylether, and diethyleneglycol diethylether. Among them, cycloalkylketone or alkyleneglycol dialkylether are more preferable. In addition, PGDM (propylene glycol dimethylether) is preferable as an alkyleneglycol dimethylether. Furthermore, PGMEA (propylene glycol monomethylether acetate) is also preferable. These organic solvents may be used independently or in a combination of two or more. The solvent may be suitably blended in a range of 70% by mass to 99% by mass with respect to the total amount of the composition for forming an intermediate layer.

In the composition for forming an intermediate layer in the present invention, as a polymer other than the silylphenylene-based polymer (A), a low conductive polymer such as polyarylene ether conventionally used in the art can be used in mixture. In this case, the amount of such a polymer mixed should be defined such that the prevention of reflection of short-wavelength light from the composition after mixing may be within a practical range. The rate of etching can be controlled on the basis of the ratio of the conventional low conductive polymer. In addition, a siloxane polymer, for example, a hydrolysate and/or condensate of alkoxysilane, may be mixed.

[4] Pattern-Forming Method

The composition for forming an intermediate layer in the present invention may be used as a film for covering the whole surface without patterning, or may be patterned and then used in high-precision patterning on a processed film layer under the patterning. An example of the pattern-forming method using the composition for forming an intermediate layer in the invention in such patterning will be given.

The pattern-forming method includes at least the following steps (i) to (iii):

(i) A step of forming an intermediate layer, where the composition for forming an intermediate layer of the present invention is applied to a processed film and an applied film is then pre-baked, thereby forming an intermediate layer.

(ii) A step of forming a resist pattern, where a resist pattern is formed on the intermediate layer prepared by the step of forming the intermediate layer.

(iii) A step of etching, where the resist pattern made in the step of forming the resist pattern is used as a mask and at least the intermediate layer is then subjected to a dry-etching process to make a pattern on the intermediate layer.

Furthermore, as an additional step subsequent to the etching step (iii), there is given

(iv) a step of etching, where the intermediate layer obtained in the step of etching the intermediate layer is used as a mask and the processed film is then subjected to a dry-etching process.

The step (iv) may be carried out in either. of two ways described below, which can be appropriately selected and used.

One of the ways is to form a pattern on a processed film by simultaneously etching the intermediate layer and the processed layer.

The other of the ways is to form a pattern on a processed film by subjecting the processed film to a dry-etching process using the pattern formed on an intermediate layer as a mask after etching the intermediate layer. In this case, an additional step of peeling and removing the resist pattern and the intermediate layer may be provided.

Etching gas used in the dry-etching process in the step (iv) is preferably halogenated gas, for example CF₄, C₄F₈, CHF₃, CH₂F₂, or SF₆.

When an intermediate layer prepared from the composition for forming an intermediate layer of the present invention is used, the formation of a pattern on an inorganic covering film, particularly a silicon-based covering film, can be facilitated.

The processed film in the step (i) may be one having a higher etching rate with respect to the halogenated gas, compared with that of the intermediate layer. Examples of the processed film include organic covering films; silicon-based covering films such as a silicon substrate, a polysilicon (Poly-Si) film, a silicon oxide (SiO₂) film, and a silicon nitride (Si₃N₄) film; and inorganic covering films such as metal wiring. These processed films may be formed by any method including a coating method and a CVD method.

The intermediate layer can be formed by applying the composition for forming an intermediate layer on the processed film and then drying by heat treatment. Furthermore, it may be hardened by sintering treatment (pre-baking) after the drying. The coating method used may be any method such as a spray method, a spin-coating method, a dip-coating method, or a roll-coating method. The film thickness of the intermediate layer is appropriately selected depending on the device to which the layer is applied.

The heat treatment may be carried out, for example, for 1 to 6 minutes at about 80 to 300° C. on a hot plate. This heat treatment is preferably stepwise-warming with three or more steps. Concretely, in an exemplified heat treatment, a first dry treatment is carried out in a first drying process for 30 seconds to 2 minutes at about 70 to 120° C. on a hot plate in the air or in an atmosphere of inert gas such as nitrogen; a second heat treatment is then carried out for about 30 seconds to 2 minutes at about 120 to 220° C.; and subsequently a third drying process is carried out for about 30 seconds to 2 minutes at about 150 to 300° C. In this way, a coating film with a uniform surface can be obtained by carrying out a stepwise drying process including three or more steps, and preferably about three to six steps.

Subsequently, the heat-treated coating film may be subjected to a sintering treatment. The sintering may be carried out at a temperature of about 300 to 400° C. in a nitrogen atmosphere.

Furthermore, an underlayer film may be provided between the processed film and the intermediate layer.

The resist pattern formed in the above step (ii) is, for example, one prepared by applying a photoresist on the intermediate layer and then drying it to form a photoresist layer, and subjecting the photoresist layer to light exposure and development. Here, the intermediate layer prepared from the composition for forming an intermediate layer of the present invention has antireflection properties particularly with regard to light at a wavelength of about 193 nm. Using ArF resist as the photoresist, a good resist pattern can be formed. Furthermore, an antireflection film may be provided between the intermediate layer and the photoresist layer. Therefore, even with exposure light at another wavelength, reflection of exposure light can be curbed by replacing the above antireflection film with another one, allowing the formation of a good resist pattern.

Here, the light exposure and development processes can be carried out using a conventional process with routine lithography.

Etching gas used in the dry-etching process in the step (iii) is, for example, halogenated gas. The halogenated gas used may be one having a higher etching rate than the intermediate layer, compared with that of the resist pattern. Specifically, such halogenated gas may be concretely, for example, C₄F₈, or CH₂F₂. Thus, using such etching gas, the resist pattern can be prevented from corrosion, while enabling etching on the intermediate layer and enabling transfer of the resist pattern to the intermediate layer.

Furthermore, an underlayer film may be formed between the processed film and the intermediate layer. Materials for the underlayer film, for example, include resins such as cresol novolak, naphthol novolak, phenol cyclopentadiene novolak, amorphous carbo, polyhydroxystyrene, acrylate, methacrylate, polyimide, and polysulfone. The underlayer film can be prepared, for example, by applying and drying a coating liquid in which the above materials are dissolved in a solvent.

In cases in which an underlayer film is formed in this way, the following steps may be added instead of the step (iv). That is, the method may include the steps of forming an underlayer film, where the underlayer film is formed between the intermediate layer and the processed film, and forming a pattern on the underlayer film, where the underlayer film is subjected to a dry-etching treatment using the pattern-formed intermediate layer as a mask.

Furthermore, using the pattern-formed intermediate layer and/or underlayer film as a mask, any pattern can be formed on a processed film by subjecting the processed film to a dry-etching treatment.

### EXAMPLES

Hereinafter, examples of the present invention will be described to provide a more concrete explanation of the present invention. However, the present invention is not limited to the following examples. Outside of the chemical agents expressly described, general commercially available chemical agents were used.

In the following example, a sylilphenylene-based polymer was used, (Al) having a molecular weight of 4,000 and having a repetitive unit represented by the chemical formula: 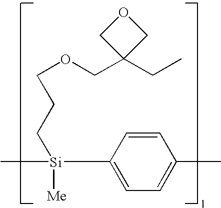
(wherein 1 is an integer representing the number of repetitive units).

A solution of 7% by mass of the polymer (A1) in propyleneglycol dimethylether (PGDM) was prepared and provided as a coating solution (composition for forming an intermediate layer).

### Example 1

[Low-Temperature Hardening Properties (Ethyl Lactate Resistance of Hardened Film)]

The composition for forming an intermediate layer was applied to a silicon wafer by a spin coat method and then heated on a hot plate for one minute at 80° C. in the atmosphere (drying treatment), followed by heat treatment at 150° C. for one minute and 250° C. for three minutes (pre-baking). The resulting covering film (intermediate layer (hard mask)) had a film thickness of 35 nm.

Two milliliters of an ethyl lactate solvent were dropped on the film of the intermediate layer and the amount of film reduced after dropping was then measured. The results showed that the amount of film reduced was 0 to 0.1 nm, so there was no substantial reduction.

### Example 2

[Absorbance, Reflective Index, and Reflectance of 193-nm Wavelength Light]

The composition for forming an intermediate layer is applied on a silicon wafer by a spin coat method and then heated on a hot plate for one minute at 80° C. in the atmosphere (drying treatment), followed by heat treatment at 150° C. for one minute and 250° C. for three minutes (pre-baking). The resulting covering film (intermediate layer (hard mask)) had a film thickness of 35 nm.

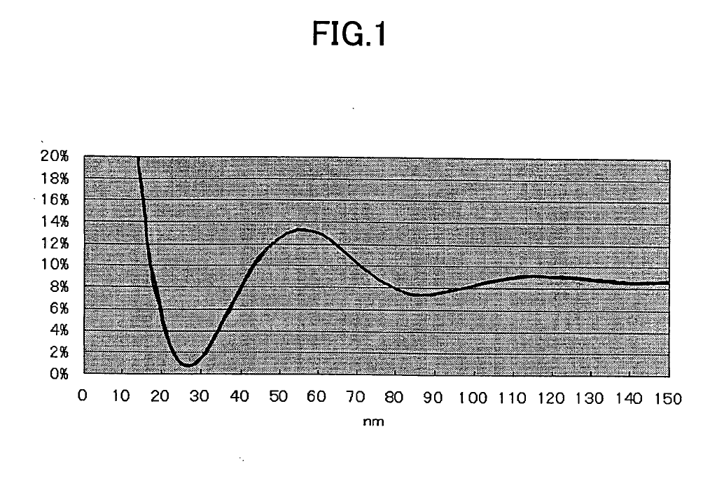

The absorbance (K) and reflective index (n) of light at 193 nm were measured using the spectral ellipsometer “WOOLLAM” (manufactured by J.A. WOOLLAM, Co., Ltd.). The results showed that, the absorbance (K) was 0.539 and the reflective index (n) was 1.558. Subsequently, the reflectance of light was simulated using the absorbance and the reflective index. Consequently, as shown in FIG. 1, the reflectance at a wavelength of 40 nm was 8%. From these results, we confirmed that all of the absorbance, reflective index, and low reflectance properties were excellent. Here, when the absorbance (k) and reflective index (n) of light at 633 mm were measured, the absorbance (k) was 0 and the reflective index (n) was 1.555.

### Example 3

[Dry-Etching Test]

Just as in the cases with Examples 1 and 2, a covering film (intermediate layer (hard mask) was prepared. The resulting intermediate layer was subjected to dry-etching and then variations in film thickness before and after the treatment. An etching rate was determined by measuring the change in film thicknesses, which were measured before and after the treatment.

The above dry-etching treatment was carried out as follows:

An etcher made of CF₄/CHF₃/He (flow rate: 120 sccm) was used to change the content of CHF₃ therein, followed by dry-etching on the covering film for 60 seconds under the conditions of a temperature of 20 to 25° C., power of 500 W, and a pressure of 300 mmHg. The ratios of CF₄/CHF₃ for the respective etchers 1, 2, 3 were defined in three ways of 30/50, 25/55, and 20/60, respectively. The results are shown in Table 1.

TABLE 1

| | Etcher | | | Etching selectivity | | |
|---|---|---|---|---|---|---|
| | Etcher 1 | Etcher 2 | Etcher 3 | Etcher 1 | Etcher 2 | Etcher 3 |
| Example 3 | 783 | 580 | 411 | — | — | — |
| Comparative | 3761 | 3660 | 3570 | 4.9 | 6.3 | 8.7 |
| Example 1 | | | | | | |
| Comparative | 1191 | 603 | — | 1.52 | 1.03 | |
| Example 2 | | | | | | |

(Comparative Examples 1 and 2)

A SiO₂ substrate (Comparative Example 1) and a CVD-Si₃N₄ (Comparative Example 2) were provided as comparative examples and subjected to the same dry-etching as that of Example 1. The results are shown in Table 1 described above. In Table 1, the term “etching selectivity” refers to values obtained by dividing the etching rate of the SiO₂ substrate and the CVD-Si₃N₄ film by the etching rate of the present invention.

From the results of Example 3 and Comparative Examples 1 and 2, an intermediate layer prepared from the composition for forming an intermediate layer in the present invention was confirmed to have a high etching resistance, compared with that of a Th.SiO₂ film. In addition, it was confirmed that a film, which has a selective ratio similar to that of the CVD-Si₃N₄ film in which an etching selective ratio is difficult to define, can be formed.

### Example 4

[Evaluation of Pattern Formation]

As with the previous examples, a coating solution (composition for forming an intermediate layer) was obtained. The resulting composition for forming an intermediate layer was applied to the Th.SiO₂ film by a spin-coating method and then heated on a hot plate at 80° C. for one minute, heated at 150° C. for one minute, and subsequently heated at 230° C. for one minute (drying treatment). The resulting intermediate film had a film thickness of 35 nm. On the intermediate layer, an acetallized ArF resist composition was applied while rotating, heated at 130° C. for 90 seconds and then subjected to a sintering treatment, thereby forming an ArF resist layer having a film thickness of 150 nm. An exposure treatment was conducted on the substrate using NSR S-306 (manufactured by Nikon Corporation). Subsequently, an exposure treatment was carried out for 60 minutes using NSR S-360C (manufactured by Nikon Corporation). After that, a development treatment was carried out for 60 seconds in a 2.38% by mass, TMAH (tetramethylammonium hydroxylate) aqueous solution to form a resist pattern (resist layer). As a result, an excellent resist pattern was formed.

Subsequently, using etching gas made of CF₆/Ar (flow rate: 10/100 sccm), the intermediate layer was dry-etched under the conditions of a temperature of −10° C., power of 1600/50 W, and a pressure of 3 mTorr, and thus the resist pattern was transferred to the intermediate layer. Consequently, the resist pattern was appropriately transferred to the intermediate layer.

Furthermore, using etching gas made of C₄F_{8/}CH₂F₂/O₂/Ar (flow rate: 7/31/2/100 sccm), the intermediate layer pattern obtained as described above was employed as a mask and the Th.SiO₂ film provided as a lower layer was then etched, under the conditions of a temperature of 20° C., power of 1600/150 W, and a pressure of 3 mTorr, resulting in an excellent pattern. Finally, patterns of lines and spaces (L/S)=120/120 nm could be formed.

As described above, the composition for forming an intermediate layer in the present invention allows the formation of an intermediate layer having excellent low-hardening properties, high absorbability of short-wavelength light, and excellent dry-etching resistance, so that it can be useful for pattern formation using lithography.

While preferred embodiments of the present invention have been described and illustrated above, it is to be understood that they are exemplary of the invention and are not to be considered to be limiting. Additions, omissions, substitutions, and other modifications can be made thereto without departing from the spirit or scope of the present invention. Accordingly, the invention is not to be considered to be limited by the foregoing description and is only limited by the scope of the appended claims.

What is claimed is:

1. A composition for forming an intermediate layer containing a silylphenylene-based polymer to be formed between a processed film and a resist layer, comprising:
the silylphenylene-based polymer (A) containing an aromatic ring, having a repetitive unit represented by the following general formula (1): 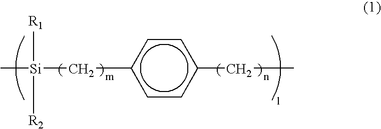
wherein, at least one of R₁ and R₂ is a cross-linking group, m and n is each an integer from 0 to 20, and 1 is an integer representing the number of repetitive units; and
a solvent (C).

2. The composition for forming an intermediate layer containing the silylphenylene-based polymer according to claim 1, wherein the R₁ in the general formula (1) is the cross-linking group an oxetanyl-group-containing alkyl group having 1 to 40 carbon atoms (but, which may have an ether bond).

3. The composition for forming an intermediate layer containing the silylphenylene-based polymer according to claim 2, wherein
the R₁ in the general formula (1) is —(CH₂)ₓO(CH₂)_{y}C(CH₂OCH₂)(CH₂)_{z}CH₃ (wherein x is an integer from 1 to 20, y is an integer from 1 to 20, and z is an integer from 0 to 20).

4. The composition for forming an intermediate layer containing the silylphenylene-based polymer according to claim 1, wherein
the R₂ in the general formula (1) is a hydrogen atom or an alkyl or aryl group having 1 to 40 carbon atoms.

5. The composition for forming an intermediate layer containing the silylphenylene-based polymer according to claim 1, wherein
a weight average molecular weight of the silylphenylene-based polymer (A) is 100 to 10,000.

6. The composition for forming an intermediate layer containing the silylphenylene-based polymer according to claim 1, further comprising a cross-linkable catalyst-generating agent (B).

7. The composition for forming an intermediate layer containing the silylphenylene-based polymer according to claim 6, wherein
the crosslinkable catalyst-generating agent (B) is an acid-generating agent that generates acid upon receiving heat or light.

8. The composition for forming an intermediate layer containing the silylphenylene-based polymer according to claim 6, wherein
the crosslinkable catalyst-generating agent (B) is an acid-generating agent that generates acid upon receiving heat or light.

9. The composition for forming an intermediate layer containing the silylphenylene-based polymer according to claim 1, wherein
the solvent (C) is propyleneglycol monomethylether acetate.

10. A pattern-forming method, comprising the steps of:
forming an intermediate layer such that the composition for forming an intermediate layer containing the silylphenylene-based polymer according to claim 1 is applied to a processed film and the applied film is then prebaked to form the intermediate layer, or such that a composition for forming an intermediate layer using an acid-generating agent or base-generating agent that generates acid or base as a cross-linkable catalyst-generating agent (B) by action of heat or receiving light is applied to a processed film and the applied film is then prebaked to form the intermediate layer;
forming a resist pattern such that the resist pattern is formed on the intermediate layer formed in the step of forming the intermediate layer; and etching to form a pattern on the intermediate layer such that at least the intermediate layer is subjected to dry-etching using the resist pattern formed in the step of forming the resist pattern as a mask.

11. The pattern-forming method according to claim 10, further comprising the steps of:
forming an underlayer film such that the underlayer film is formed between the intermediate layer and the processed film; and
forming a pattern on the underlayer film such that the underlayer film is dry-etched using the pattern-formed intermediate layer as a mask.

12. The pattern-forming method according to claim 10 or 11 further comprising the step of:
forming a pattern on the processed film such that the processed film is subjected to dry-etching using the pattern-formed intermediate layer and/or underlayer film as a mask.

13. The pattern-forming method according to claim 12, wherein
the dry-etching on the processed film uses a halogenated gas as an etching gas.

14. The pattern-forming method according to claim 10, wherein
the processed film is an inorganic covering film.
